(19) United States
(12) Patent Application Publication
(10) Pub. No.: US 2021/0384012 A1
(43) Pub. Date: Dec. 9, 2021

(54) SUBSTRATE PROCESSING APPARATUS

(71) Applicant: Samsung Electronics Co., Ltd., Suwon-si (KR)

(72) Inventors: Jinhyuk CHOI, Suwon-si (KR); Siqing LU, Seongnam-si (KR); Sangki NAM, Seongnam-si (KR); Keesoo PARK, Hwaseong-si (KR); Soonam PARK, Seongnam-si (KR)

(73) Assignee: Samsung Electronics Co., Ltd., Suwon-si (KR)

(21) Appl. No.: 17/173,702

(22) Filed: Feb. 11, 2021

(30) Foreign Application Priority Data
Jun. 4, 2020 (KR) 10-2020-0067867

(51) Int. Cl. H01J 37/32

(52) U.S. Cl. CPC H01J 37/32467; H01J 37/32715; H01J 2237/2007; H01J 37/3222; H01J 37/3244

(57) ABSTRACT

A substrate processing apparatus includes a chamber housing with an upper portion opened, the chamber housing defining a reaction space, a susceptor configured to support a substrate in the chamber housing, and a dielectric cover covering an upper portion of the chamber housing. The dielectric cover includes a dielectric lid, and a mode modifying assembly arranged around the dielectric lid to be spaced apart from the dielectric lid, the mode modifying assembly configured to adjust a distance from the dielectric lid.

### CROSS-REFERENCE TO RELATED APPLICATION

This application is based on and claims priority under 35 U. S. C. § 119 to Korean Patent Application No. 10-2020-0067867, filed on Jun. 4, 2020, in the Korean Intellectual Property Office, the disclosure of which is incorporated by reference herein in its entirety.

### BACKGROUND

Inventive concepts relate to a substrate processing apparatus, and more particularly, to a substrate processing apparatus capable of preventing or reducing product defects caused by particles and/or reducing manufacturing cost of a product.

In a substrate processing apparatus using plasma, particles are generated due to various causes. The particles contact a surface of a processed substrate and may cause product defects, leading to decreased yield and/or decreased reliability. Therefore, in order to prevent or reduce the product defects from occurring due to the particles, it is desirable to prevent or reduce the likelihood of the particles from contacting the substrate.

### SUMMARY

Inventive concepts relate to a substrate processing apparatus capable of preventing or reducing product defects caused by particles and/or reducing manufacturing cost of a product.

According to some example embodiments of inventive concepts, there is provided a substrate processing apparatus including a chamber housing with an upper portion opened, the chamber housing defining a reaction space, a susceptor configured to support a substrate in the chamber housing, and a dielectric cover covering an upper portion of the chamber housing. The dielectric cover includes a dielectric lid, and a mode modifying assembly arranged around the dielectric lid to be spaced apart from the dielectric lid, the mode modifying assembly configured to adjust a distance from the dielectric lid.

According to some example embodiments of inventive concepts, there is provided a substrate processing apparatus including a chamber housing with an upper portion opened, the chamber housing defining a reaction space and including a gas supply pipe in a side wall, a susceptor configured to support a substrate in the chamber housing, and a dielectric cover covering an upper portion of the chamber housing. The gas supply pipe is configured such that, in an upper portion of the susceptor, a flow of a gas by a convection is more dominant than a flow of a gas by diffusion.

According to some example embodiments of inventive concepts, there is provided a substrate processing apparatus including a chamber housing with an upper portion opened, the chamber housing defining a reaction space, a susceptor configured to support a substrate in the chamber housing, a dielectric cover including a reworked dielectric lid and a mode modifying assembly arranged around the reworked dielectric lid, the mode modifying assembly spaced apart from the reworked dielectric lid and covering an upper portion of the chamber housing, a high frequency antenna on the dielectric lid, a microwave generator connected to the high frequency antenna, and a plurality of gas supply pipes provided on a side wall of the chamber housing. The mode modifying assembly is apart from the dielectric lid with a dielectric spacer therebetween, and the plurality of gas supply pipes are configured such that a flow of a gas by a convection is more dominant than that of a gas by diffusion in an upper portion of the susceptor.

### BRIEF DESCRIPTION OF THE DRAWINGS

Some example embodiments of inventive concepts will be more clearly understood from the following detailed description taken in conjunction with the accompanying drawings in which:

FIG. 1 is a schematic diagram illustrating a substrate processing system according to some example embodiments of inventive concepts;

FIG. 2 is a side sectional view illustrating a substrate processing apparatus according to some example embodiments of inventive concepts;

FIG. 3 is an enlarged view illustrating the region A of FIG. 2 in detail;

FIG. 4A is a graph illustrating strength of an electric field in a surface under a dielectric lid in a radial direction immediately after exchanging the dielectric lid;

FIG. 4B is a graph illustrating strength of an electric field in a surface under a dielectric lid of which the thickness is reduced through a rework in a radial direction together with the strength of the electric field in FIG. 4A;

FIG. 4C is a graph illustrating strength of an electric field in a surface under a dielectric lid after a mode modifier is arranged on the outside of the reworked dielectric lid in a radial direction together with the strength of the electric field in FIG. 4A;

FIG. 5 is a plan view illustrating a mode modifier and a dielectric spacer according to some example embodiments of inventive concepts;

FIG. 6 is a plan view illustrating a mode modifier and a dielectric spacer according to some example embodiments of inventive concepts;

FIG. 7A is a plan view illustrating a mode modifier and a dielectric spacer according to some example embodiments of inventive concepts and FIG. 7B is a cross-sectional view illustrating a cross-section taken in the radial direction r of FIG. 7A;

FIGS. 8A and 8B are a plan view and a side view illustrating an example in which the fourth spacer ring of FIGS. 7A and 7B is exchanged with a fifth mode modifying ring;

FIGS. 9A and 9B are a plan view and a side view illustrating an example in which the fourth mode modifying ring of FIGS. 7A and 7B is exchanged with a fifth spacer ring;

FIGS. 10A and 10B are a plan view and a side view illustrating an example in which the fourth spacer ring of FIGS. 7A and 7B is exchanged with a fifth mode modifying ring and the fourth mode modifying ring is exchanged with a fifth spacer ring;

FIG. 11 is an enlarged view illustrating the region B of FIG. 2 in a substrate processing apparatus according to some example embodiments of inventive concepts in detail;

FIG. 12 is an enlarged view illustrating the region B of FIG. 2 in a substrate processing apparatus according to some example embodiments of inventive concepts in detail; and

FIG. 13 is a side sectional view illustrating a substrate processing apparatus including a second processing gas supply pipe according to some example embodiments of inventive concepts.

### DETAILED DESCRIPTION OF SOME EXAMPLE EMBODIMENTS

Hereinafter, some example embodiments of inventive concepts will be described in detail with reference to the accompanying drawings. Like reference numerals refer to like elements throughout and previously given description will be omitted.

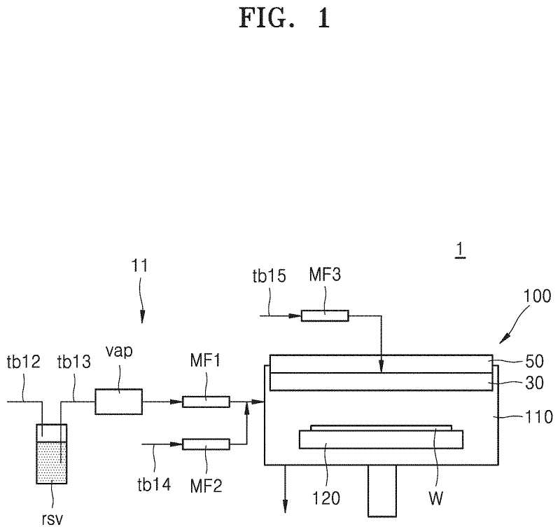

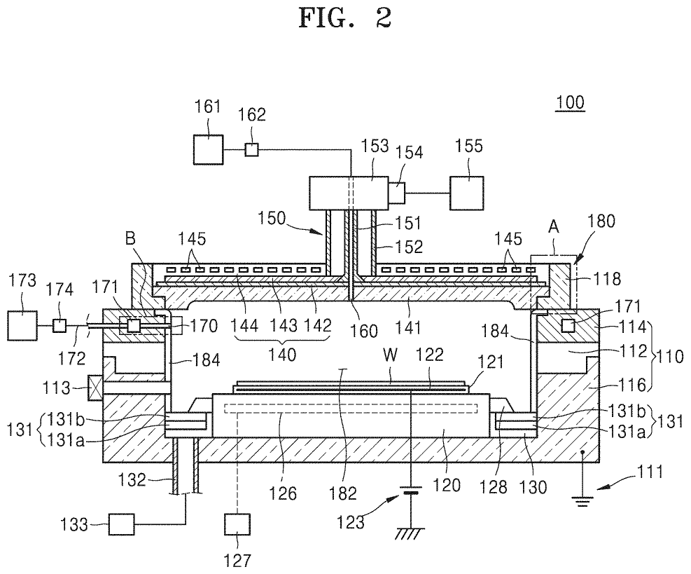

FIG. 1 is a schematic diagram illustrating a substrate processing system 1 according to some example embodiments of inventive concepts.

Referring to FIG. 1, the substrate processing system 1 includes a raw material supply unit 11, raw material supply controllers MF1, MF2, and MF3, and a substrate processing apparatus 100.

The raw material supply unit 11 includes a raw material vessel rsv accommodating a liquid raw material and a pressurizing gas supply pipe tb12 supplying a pressurizing gas (for example, an inert gas such as helium (He), nitrogen (N2), and/or argon (Ar)) for pressurizing the liquid raw material accommodated in the raw material vessel rsv and discharging the pressurized liquid raw material from the raw material vessel rsv. Alternatively or additionally, a raw material supply pipe tb13 for supplying the liquid raw material from the raw material vessel rsv to a vaporizer vap may be provided between the raw material vessel rsv and the vaporizer vap.

The vaporizer vap may vaporize the liquid raw material supplied from the raw material vessel rsv by heating and/or depressurizing the liquid raw material, and may convert the liquid raw material into a raw material in vapor phase. When a raw material is already in vapor phase, the vaporizer vap may be omitted. A volumetric flow rate of the raw material in vapor phase may be controlled by the raw material supply controller MF1 to be supplied to the substrate processing apparatus 100. The raw material supply controller MF1 may be or may include a mass flow controller (MFC); however, example embodiments are not limited thereto. The raw material in vapor phase may be a second processing gas described with reference to FIG. 2 later.

In some example embodiments, an inert gas supply pipe tb14 supplying an inert gas such as N₂, He, and/or Ar may be provided to the raw material supply unit 11. A volumetric flow rate of the inert gas may be controlled by the raw material supply controller MF2 to be supplied to the substrate processing apparatus 100. The raw material supply controller MF2 may be or include a mass flow controller; however, example embodiments are not limited thereto. A pipe may be configured so that the inert gas is supplied to the substrate processing apparatus 100 together with the raw material in vapor phase.

The substrate processing apparatus 100 includes a chamber housing 110 defining a reaction space. A susceptor 120 supporting a substrate W to be processed may be provided in the chamber housing 110. The susceptor 120 may support and fix the substrate W. The susceptor may be, include, or correspond to a chuck such as an electrostatic chuck; however, example embodiments are not limited thereto.

A gas supply system 30 capable of supplying another reaction gas may be further provided in the substrate processing apparatus 100. The gas supply system 30 may be or include a shower head and/or a tube opened toward an inner space of the substrate processing apparatus 100. The reaction gas may be or include a first processing gas to be described later with reference to FIG. 2, and may be supplied through a gas supply pipe tb15. Then, a volumetric flow rate of the reaction gas may be controlled by a raw material supply controller MF3 to be supplied to the substrate processing apparatus 100. The raw material supply controller MF3 may be or include a mass flow controller; however, example embodiments are not limited thereto.

A microwave generator, e.g. a microwave generating device 50 may be further provided on the gas supply system 30.

Referring to FIG. 2, the substrate processing apparatus will be described in more detail. FIG. 2 is a side sectional view illustrating the substrate processing apparatus 100 according to some example embodiments of inventive concepts.

Referring to FIG. 2, the substrate processing apparatus 100 includes the chamber housing 110. The chamber housing 110 may include a lower chamber 116, a lower gas ring 112, and an upper gas ring 114. A dome plate 118 may be on and combined with the upper gas ring 114. Alternatively or additionally, a dielectric lid 141 may be provided as a ceiling of a reaction space 182 in the chamber housing 110. The chamber housing 110, the dome plate 118, and the dielectric lid 141 may form, or form components of, a processing chamber 180 defining the reaction space 182.

A side wall liner 184 may be provided on an inner side wall of the reaction space 182 of the chamber housing 110 to protect the lower chamber 110, the lower gas ring 112, and the upper gas ring 114 from plasma. The side wall liner 184 may be formed of an insulating material such as at least one of quartz, Al₂O₃, AlN, or Y₂O₃.

In particular, the side wall liner 184 may be formed to cover all or nearly all of the exposed lateral area of the upper gas ring 114 from an exposed side wall of the metallic lower chamber 116. Therefore, the metallic lower chamber 116, the lower gas ring 112, and the upper gas ring 114 may be completely protected or nearly completely protected against plasma.

In some example embodiments, through a gate valve 113 provided on one side of the metallic lower chamber 116, the substrate W may be brought into and/or taken out from the reaction space 182.

On a bottom surface of the chamber housing 110, the susceptor 120 as an arrangement unit arranging the substrate W may be provided. The susceptor 120 may have a cylindrical shape. The susceptor 120 may be formed of an inorganic material such as at least one of quartz or AlN or a metal such as aluminum (Al).

On an upper surface of the susceptor 120, an electrostatic chuck 121 may be provided. The electrostatic chuck 121 may be configured so that an electrode 122 is inserted between insulating materials. The electrode 122 may be connected to a direct current (DC) power source 123 provided outside the chamber housing 110. By generating Coulomb force in a surface of the susceptor 120 by the DC power source 123, the substrate W may be electrostatically adsorbed and/or electrostatically chucked onto the susceptor 120.

A heater/cooler 126 may be provided in the susceptor 120. The heater/cooler 126 may be connected to a temperature controller 127 for controlling heating/cooling strength thereof. For example, a temperature of the susceptor 120 may be controlled by the temperature controller 127 so that a temperature of the substrate W arranged on the susceptor 120 may be maintained at a desired temperature. The temperature controller 127 may include a thermostat and/or a thermcouple; however, example embodiments are not limited thereto.

A susceptor guide 128 for guiding the susceptor 120 is provided around the susceptor 120. An insulating material such as ceramic or quartz may be used as the susceptor guide 128.

An elevating pin for elevating or changing the elevation of the substrate W while supporting the substrate W thereunder may be provided in the susceptor 120. The elevating pin may be inserted into and pass through a through hole formed in the susceptor 120 and may protrude from the upper surface of the susceptor 120. Alternatively or additionally, at least three elevating pins for supporting the substrate W may be provided. The at least three elevating pins may be arranged symmetrically; however, example embodiments are not limited thereto.

Around the susceptor 120, an exhaust space 130 surrounding the susceptor 120 in the form of a ring may be formed. An annular baffle plate 131 may be provided on the exhaust space 130 to uniformly or nearly uniformly exhaust a gaseous material in the substrate processing apparatus 100. A plurality of exhaust holes may be formed in the annular baffle plate 131. The annular baffle plate 131 may include a first layer 131a and a second layer 131b, and the second layer 131b may be closer to the reaction space 182 than the first layer 131a is.

In some example embodiments, the annular baffle plate 131 may be electrically connected to the metallic lower chamber 116 formed of a conductive metal material. Alternatively or additionally, the metallic lower chamber 116 may be grounded through a ground 111. In this case, the annular baffle plate 131 may form a ground path by electrical connection to the metallic lower chamber 116.

Exhaust pipes 132 may be connected to a bottom of the exhaust space 130, which is a bottom surface of the substrate processing apparatus 100. The number of exhaust pipes 132 may be arbitrarily set, and the plurality of exhaust pipes 132 may be provided in a circumferential direction. The exhaust pipes 132 may be connected to an exhaust apparatus 133 including, for example, a vacuum pump. The exhaust apparatus 133 may be formed to depressurize an atmosphere in the substrate processing apparatus 100 to a predetermined degree of vacuum.

A radio frequency (RF) antenna device 140 supplying a microwave for generating plasma may be provided on the dielectric lid 141 of the substrate processing apparatus 100. The RF antenna device 140 may include a slot plate 142, a slow-wave plate 143, and a shield cover 144.

A dielectric such as at least one of quartz, Al₂O₃, or AlN may be used as the dielectric lid 141 so that the dielectric lid 141 may transmit the microwave well. The dielectric lid 141 may adhere to the dome plate 118 by using a sealing member such as an O-ring. In some example embodiments, the dielectric lid 141 may be or include a quartz dome.

The slot plate 142 may be positioned on the dielectric lid 141 and may be arranged to face the susceptor 120. A plurality of slots may be formed in the slot plate 142, and the slot plate 142 may function as an antenna. A conductive material such as at least one of copper (Cu), aluminum (Al), nickel (Ni) and so forth may be used as the slot plate 142.

The slow-wave plate 143 is provided on the slot plate 142 and may reduce a wavelength and/or increase a frequency of the microwave. A low-loss dielectric material such as at least one of quartz, Al₂O₃, AlN etc. may be used as the slow-wave plate 143.

The shield cover 144 may be provided on the slow-wave plate 143 to cover the slot plate 142 and the slow-wave plate 143. In the shield cover 144, for example, a plurality of annular channels 145 through which a cooling medium flows may be provided. By the cooling medium flowing through the plurality of annular channels 145, temperatures of the dielectric lid 141, the slot plate 142, the slow-wave plate 143, and the shield cover 144 may be adjusted to specific (or, alternatively, predetermined) temperatures.

A coaxial waveguide 150 may be connected to the center of the shield cover 144. The coaxial waveguide 150 may include an inner conductor 151 and an outer pipe 152. The inner conductor 151 may be connected to the slot plate 142. An end of the inner conductor 151 at the side of the slot plate 142 may be formed to be conical and configured to efficiently transmit the microwave to the slot plate 142.

A mode converter 153 capable of converting a mode of the microwave into a specific (or, alternatively, predetermined) vibration mode, a rectangular waveguide 154, and a microwave generating device 155 generating the microwave may be sequentially connected to the coaxial waveguide 150. The microwave generating device 155 may generate the microwave with a specific or predetermined frequency, for example, 2.45 GHz. Power of no less than about 2,000 W may be applied to the microwave generating device 155. Power of about 3,000 W to about 3,500 W may also be applied to the microwave generating device 155. The microwave generating device 155 may be or include a magnetron.

A method of generating plasma by the substrate processing device 100 may be in a capacitive manner and/or in an inductive manner. Alternatively or additionally, the microwave generating device 155 may be connected to a remote plasma generator such as a plasma tube.

By such a configuration, the microwave generated by the microwave generating device 155 is sequentially transmitted to the rectangular waveguide 154, the mode converter 153, and the coaxial waveguide 150, is supplied to the RF antenna device 140, is compressed by the slow-wave plate 143 and converted to have a shorter wavelength, generates circularly polarized waves by the slot plate 142, and is emitted from the slot plate 142 to the reaction space 182 through the dielectric lid 141. By the microwave, in the reaction space 182, a processing gas is plasmarized, e.g. ionized, and plasma processing is performed on the substrate W by plasma.

Here, the RF antenna device 140, the coaxial waveguide 150, the mode converter 153, the rectangular waveguide 154, and the microwave generating device 155 may form, correspond to, or be included in a plasma generator.

In the center of the RF antenna device 140, a first processing gas supply pipe 160 as a first processing gas supply unit is provided. The first processing gas supply pipe 160 passes through the RF antenna device 140, and one end of the first processing gas supply pipe 160 is open through a lower surface of the dielectric lid 141. Alternatively or additionally, the first processing gas supply pipe 160 passes through the inner conductor 151 of the coaxial waveguide 150 and is inserted into and passes through the mode converter 153 so that the other end of the first processing gas supply pipe 160 may be connected to a first processing gas supply source 161. In the first processing gas supply source 161, as a processing gas, for example, an H2 gas may be stored. However, as required and/or desired, other gases such as trisilylamine (TSA), an N₂ gas, and/or an Ar gas may be further stored individually. In addition, with respect to the first processing gas supply pipe 160, a supply equipment group 162 including a valve and/or a flux modifier modifying flow/mass flow controller of the first processing gas is provided.

As illustrated in FIG. 2, on a side surface of the processing chamber 180, a plurality of second processing gas supply pipes 170 as second processing gas supply units are provided. For example, a plurality of second processing gas supply pipes 170 such as 24 second processing gas supply pipes 170 may be provided on a circumference of the side surface of the processing chamber 180, and may be arranged at equal intervals. One end of each of the second processing gas supply pipes 170 is open on a side surface of the processing chamber 180 and the other end thereof is connected to a buffer 171.

The buffer 171 may be annularly provided in the side surface of the processing chamber 180 and may be commonly provided in the plurality of second processing gas supply pipes 170. A second processing gas supply source 173 is connected to the buffer 171 through a supply pipe 172. In the second processing gas supply source 173, as a processing gas, a reaction gas such as at least one of TSA, an N₂ gas, an H₂ gas, and an Ar gas are individually stored. Alternatively or additionally, in the supply pipe 172, a supply equipment group 174 including a valve or a mass flow rate controller controlling flow of the second processing gas may be provided. As illustrated in FIG. 2, the second processing gas supplied by the second processing gas supply source 173 may be introduced to the buffer 171 through the supply pipe 172. The pressure may be equalized in a circumferential direction in the buffer 171, and then the second processing gas may be supplied to the processing chamber 180 through the second processing gas supply pipes 170.

It is noted that, in the substrate processing apparatus 100 illustrated in FIG. 2, more particles are generated and even accumulated as the substrate W is repeatedly processed. As a result, more particles are attached to the substrate W so that product defects continuously increase. For example, the particles may fall onto the substrate W and may cause shorts and/or opens leading to lower yield, and/or may cause reliability defects.

However, as a quartz dome corrodes as the substrate W is repeatedly processed, parts of the quartz dome minutely fall off so that particles are generated. In order to solve or reduce the impact of the problem, a rework method of smoothing an inner surface of a quartz dome facing the reaction space 182 may be considered. However, because the processing of the substrate W, which is performed by the substrate processing apparatus 100, is extremely sensitive to a thickness of the quartz dome, it is difficult to apply such rework and the expensive quartz dome is to be exchanged.

Nonetheless product defects may be reduced, e.g. remarkably reduced by applying a first method of reducing the number of particles generated in the quartz dome and a second method of preventing or reducing the generated particles from reaching the surface of the substrate W, independently or in combination based on such recognition.

In particular a mode in which the processing of the substrate W is insensitive to a change in the thickness of the quartz dome, may be selected by modifying a microwave reflection boundary of the quartz dome in a first method.

Alternatively or additionally, particles falling off from the quartz dome may be prevented or reduced in likelihood of reaching the substrate W by at least partially ultrasonically supplying the gas from a side wall of the chamber housing 110 in the a method.

The region A of FIG. 2 relates to the first method, and the region B of FIG. 2 relates to the second method. The two methods individually contribute to preventing or reducing product defects from being caused by the particles. However, when the two methods are combined, a defect reduction effect greater than the simple combination of effects of the two methods may be obtained. Hereinafter, the first method and the second method will be described in more detail.

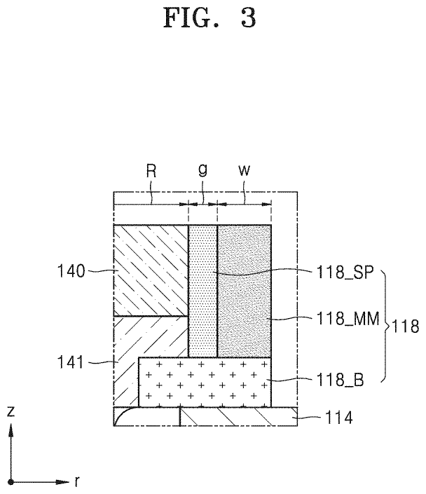

FIG. 3 is an enlarged view illustrating a region A of FIG. 2 in detail.

Referring to FIG. 3, the dome plate 118 includes a mode modifier 118_MM. The mode modifier 118_MM may be arranged outside the dielectric lid 141 at a uniform distance from the dielectric lid 141. The mode modifier 118_MM is a structure/assembly having one or more components, e.g. a mode modifying structure/assembly. For example the mode modifying structure/assembly may be a mode modifying plate, a mode modifying reflector, a mdoe modifying mirror, a mode modifying wall, a mode modifying ring, a mode modifying ringed wall, a resonance ring, etc. The mode modifier 118_MM may include components, such as metal components, that modify reflection boundaries, e.g. locations of reflection boundaries, of the quartz dome. The mode modifier 118_MM may include an electrically conductive material such as a metal. In some embodiments, the mode modifier 118_MM may be formed of a metal. In some example embodiments, the mode modifier 118_MM may include at least one of iron (Fe), aluminum (Al), copper (Cu), chrome (Cr), nickel (Ni), molybdenum (Mo), titanium (Ti), niobium (Nb), manganese (Mn), or an alloy of the above metals.

In some example embodiments, the mode modifier 118_MM may be formed of a composite material of a metal and a nonmetal. At this time, the metal may include at least one of Fe, Al, Cu, Cr, Ni, Mo, Ti, Nb, Mn, or an alloy of the above metals.

In some example embodiments, the nonmetal may include an electrically conductive polymer such as at least one of polyacetylene, polythiophene, poly(thiophene vinylene), polyaniline, poly(p-phenylene), poly(p-phenylene vinylene), poly(p-phenylene sulfide), polypyrrole, polyfuran, or poly(3,4-ethylene dioxythiophene) (PEDOT).

In some example embodiments, the nonmetal may include a polymer that is an electrical insulator such as at least one of polyethylene, polypropylene, polystyrene, polyvinylchloride, polyethylene terephthalate, poly methyl methacrylate, polyvinyl alcohol, polyvinylidene chloride (PVdC), polyvinylidene fluoride (PVdF), or ABS resin.

In some example embodiments, the dome plate 118 may further include a dielectric spacer 118_SP. The dielectric spacer 118_SP may be between the dielectric lid 141 and the mode modifier 118_MM. The dielectric spacer 118_SP may be a vacuum, air, an inert gas, nitrogen, carbon dioxide, polyamide, polypropylene, polyvinylchloride, polytetrafluoroethylene, polysiloxane, alumina, quartz or a combination thereof.

As described above, the dielectric spacer 118_SP may be or include a gas such as air such as clean dry air, an inert gas, nitrogen, or carbon dioxide. In such a case, a space as the dielectric spacer 118_SP may be filled with such a gas. Alternatively or additionally, the dielectric spacer 118_SP may be vacuous. In such a case, the space as the dielectric spacer 118_SP may be an empty space.

The mode modifier 118_MM may have a dimension of a first width w in a radial direction of the dielectric lid 141. Alternatively or additionally, the mode modifier 118_MM may be apart from the dielectric lid 141 with a second width g in the radial direction. Because the mode modifier 118_MM is apart from the dielectric lid 141 with the dielectric spacer 118_SP therebetween, the second width g may be a dimension of the dielectric spacer 118_SP in the radial direction.

The first width w and the second width g may be determined considering a frequency of the microwave applied to the dielectric lid 141, a dielectric constant of the dielectric spacer 118_SP, and a resonance characteristic in the dielectric lid 141.

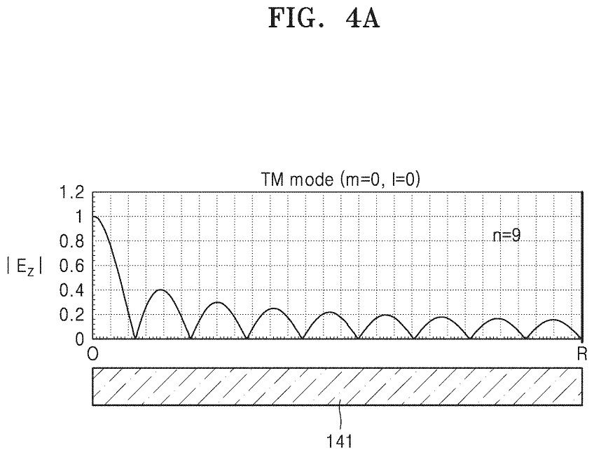

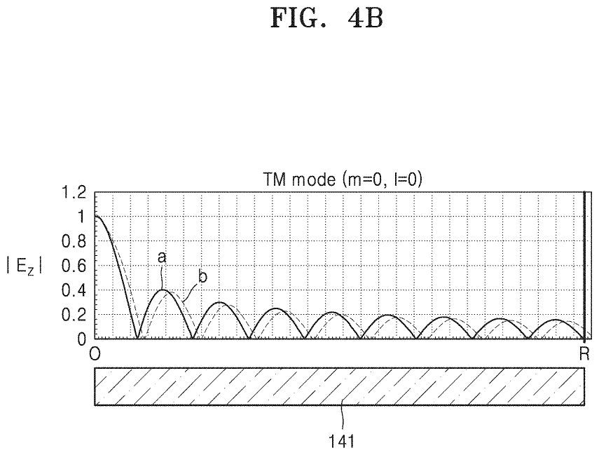

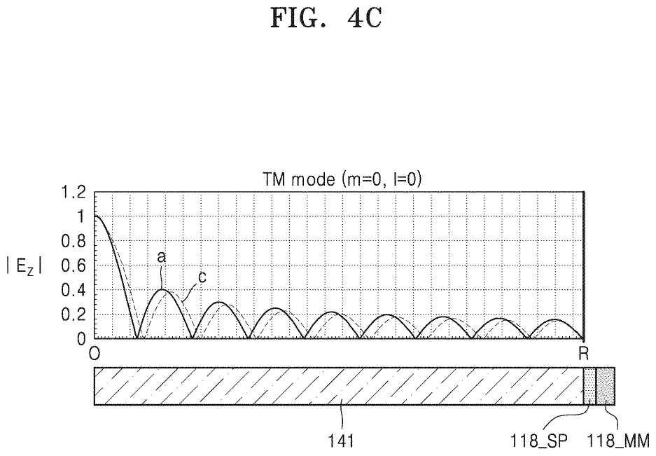

FIG. 4A is a graph illustrating strength of an electric field in a surface (l=0) under the dielectric lid 141 in a radial direction immediately after exchanging the dielectric lid 141.

Referring to FIG. 4A, electric field resonance with nine peaks is formed from an origin O to an outer circumference R.

FIG. 4B is a graph illustrating strength “b” of the electric field in the radial direction at the lower surface (l=0) of the reworked dielectric lid 141 of which the thickness is reduced through a rework together with strength “a” of the electric field in FIG. 4A.

The rework, e.g. the reworking process of the dielectric lid 141, may be or include grinding and/or smoothing the lower surface of the dielectric lid 141 in order to prevent or reduce the likelihood of particle defects occurring as the dielectric lid 141 is used.

Referring to FIG. 4B, in comparison with the strength “a” of the electric field before the rework, the strength “b” of the electric field after the rework changes according to a position in the radial direction. In particular, the strength “b” of the electric field after the rework does not become 0 in a position of the outer circumference R of the reworked dielectric lid 141. Therefore, resonance does not occur in the reworked dielectric lid 141 after the rework.

FIG. 4C is a graph illustrating strength “c” of the electric field in the radial direction at the lower surface (l=0) of the reworked dielectric lid 141 in the radial direction after the mode modifier 118_MM is arranged outside the reworked dielectric lid 141 together with the strength “a” of the electric field in FIG. 4A.

As illustrated a resonance aspect of the microwave in the reworked dielectric lid 141 may be changed by arranging the mode modifier 118_MM outside the reworked dielectric lid 141 and the reworked dielectric lid 141 may be continuously recycled, or a number of reworking/recycling of the dielectric lid 141 may be increased, by using the change in the resonance aspect of the microwave in the reworked dielectric lid 141.

Referring to FIG. 4C, as a result of arranging the mode modifier 118_MM outside the reworked dielectric lid 141, the strength of the electric field in the radial direction at the lower surface (l=0) of the reworked dielectric lid 141 may become 0 or close to 0 at the outer circumference R of the reworked dielectric lid 141. At this time, so that the strength of the electric field at the outer circumference R of the reworked dielectric lid 141 becomes 0, the dielectric constant of the dielectric spacer 118_SP, the dimensions of the first and second widths w and g (refer to FIG. 3), and a ratio between the first width w and the second width g may be appropriately modified.

In some example embodiments, the dielectric constant of the dielectric spacer 118_SP for a vacuum may be, for example, 1 to about 15. When the dielectric constant of the dielectric spacer 118_SP is too large, a mode modifying effect by the mode modifier 118_MM may not be sufficient.

In some example embodiments, the ratio between the first width w and the second width g may be about 1:0.1 to about 1:10, about 1:0.2 to about 1:5, or about 1:0.4 to about 1:2.5. When the ratio between the first width w and the second width g is too large or too small, the mode modifying effect may be insufficient.

In some example embodiments, the first width w may be about 3 mm to about 50 mm, about 4 mm to about 40 mm, about 5 mm to about 35 mm, about 7 mm to about 30 mm, or about 9 mm to about 25 mm. In addition, the second width g may be about 3 mm to about 50 mm, about 4 mm to about 40 mm, about 5 mm to about 35 mm, about 7 mm to about 30 mm, or about 9 mm to about 25 mm.

When the first width w and/or the second width g is too large, it may be difficult to adopt the mode modifier 118_MM and the dielectric spacer 118_SP in the substrate processing apparatus 100. When the first width w and/or the second width g is too small, the mode modifying effect may be insufficient.

Referring back to FIG. 3, the dome plate 118 may further include a body 118_B under the mode modifier 118_MM. In some embodiments, the body 118_B may be omitted. In this case, the mode modifier 118_MM may directly contact an upper surface of the upper gas ring 114.

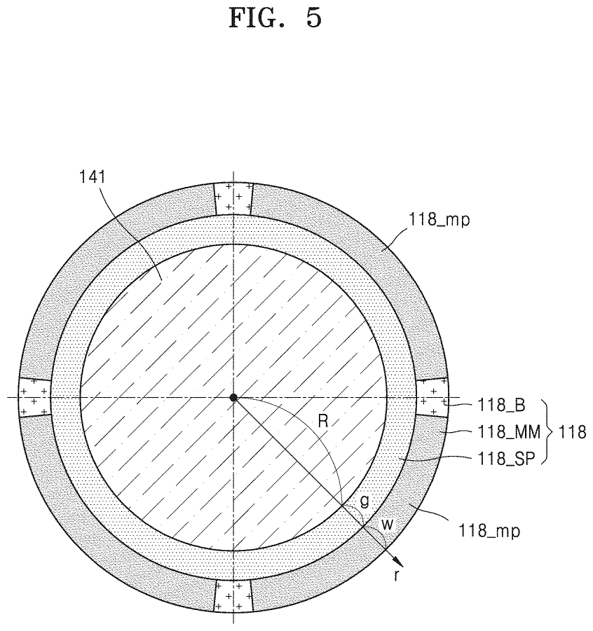

FIG. 5 is a plan view illustrating the mode modifier 118_MM and the dielectric spacer 118_SP according to some example embodiments of inventive concepts.

Referring to FIG. 5, the mode modifier 118_MM may include a plurality of modifying pieces 118_mp. In FIG. 5, it is illustrated that four modifying pieces 118_mp are arranged around the reworked dielectric lid 141. However, those of ordinary skill in the art would understand that two, three, five or more modifying pieces may be arranged around the reworked dielectric lid 141. Further an arc-length of each of the mode modifying pieces 118_mp may be the same as, or different from, each other.

The modifying pieces 118_mp may be arc-shaped. In addition, in the radial direction, a width of each of the modifying pieces 118_mp may be equal to the first width w.

The dielectric spacer 118_SP may be between the modifying pieces 118_mp and the reworked dielectric lid 141. In some example embodiments, the dielectric spacer 118_SP may be annular so as to completely surround the reworked dielectric lid 141. As described above, the dielectric spacer 118_SP may be vacuous or gaseous. In such a case, the dielectric spacer 118_SP may extend to a space between two adjacent modifying pieces 118_mp.

As substrates W are repeatedly processed while using the reworked dielectric lid 141, the problem of product defects may occur again due to the generation of the particles. In this case, the rework may be performed again on the reworked dielectric lid 141. The rework may smoothen the surface of the quartz dome on the side facing the reaction space 182 (refer to FIG. 2) as described above.

When the rework is performed again, because a thickness of the reworked dielectric lid 141 additionally changes, the resonance characteristic in the reworked dielectric lid 141 may change again and the problem described with reference to FIG. 4B may occur. In this case, by modifying a position of the mode modifier 118_MM in the radial direction or changing a thickness of the mode modifier 118_MM, as described above with reference to FIG. 4C, the resonance characteristic may be normalized.

When the position of the mode modifier 118_MM is modified, a direction of movement of the mode modifier 118_MM may be a +r or −r direction in accordance with the changed resonance characteristic.

When the position of the mode modifier 118_MM is changed as described above, the dielectric spacer 118_SP may be exchanged as required and/or desired. For example, when the mode modifier 118_MM is moved in the +r direction, the dielectric spacer 118_SP may be exchanged with a dielectric spacer with a greater second width g. To the contrary, when the mode modifier 118_MM is moved in the -r direction, the dielectric spacer 118_SP may be exchanged with a dielectric spacer with a smaller second width g. When the dielectric spacer 118_SP is vacuous or gaseous, it may be unnecessary to exchange the dielectric spacer 118_SP.

When the thickness of the mode modifier 118_MM is changed, the mode modifier 118_MM may be exchanged. By exchanging the mode modifier 118_MM, the first width w of the mode modifier 118_MM in the radial direction may be increased or reduced considering the changed resonance characteristic.

When the thickness of the mode modifier 118_MM is changed, the dielectric spacer 118_SP may be exchanged as required. For example, when the thickness of the mode modifier 118_MM is reduced, the dielectric spacer 118_SP may be exchanged with a dielectric spacer with a larger second width g. To the contrary, when the thickness of the mode modifier 118_MM is increased, the dielectric spacer 118_SP may be exchanged with a dielectric spacer with a smaller second width g. When the dielectric spacer 118_SP is vacuous or gaseous, it may be unnecessary to exchange the dielectric spacer 118_SP.

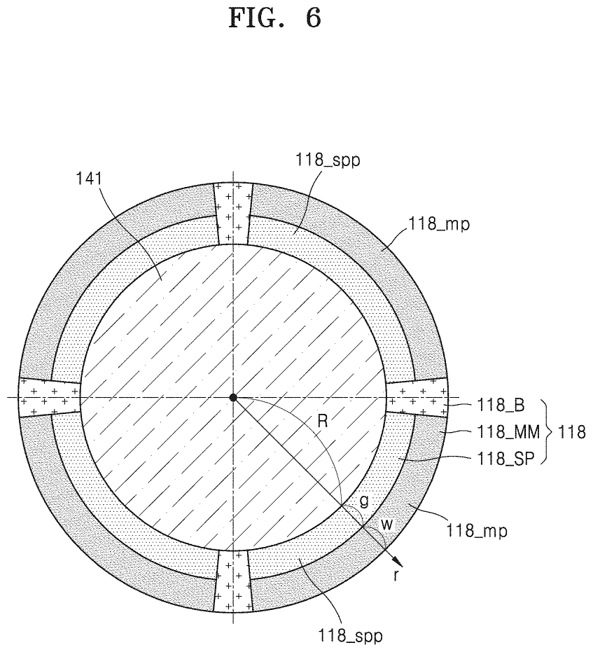

FIG. 6 is a plan view illustrating the mode modifier 118_MM and the dielectric spacer 118_SP according to some example embodiments of inventive concepts. The dielectric spacer 118_SP of FIG. 6 may be different from the dielectric spacer 118_SP according to the example embodiments illustrated FIG. 5 in that the dielectric spacer 118_SP of FIG. 6 includes a plurality of spacer pieces 118_spp corresponding to the plurality of modifying pieces 118_mp. Therefore, hereinafter, such a difference will be mainly described.

The dielectric spacer 118_SP includes the plurality of spacer pieces 118_spp. The plurality of spacer pieces 118_spp may respectively correspond to the plurality of modifying pieces 118_mp. In FIG. 6, it is illustrated that one modifying piece 118_mp corresponds to one spacer piece 118_spp. However, inventive concepts is not limited thereto. In some embodiments, a plurality of modifying pieces 118_mp may correspond to one spacer piece 118_spp. In some embodiments, one modifying piece 118_mp may correspond to a plurality of spacer pieces 118_spp.

In some example embodiments, the spacer piece 118_spp may have a shape corresponding to that of the modifying piece 118_mp. For example, an outer side of the spacer piece 118_spp may match with an inner side of the modifying piece 118_mp.

In some example embodiments, the spacer piece 118_spp may be arc-shaped. In addition, in the radial direction, a width of each of the spacer pieces 118_spp may be equal to the second width g.

Like in example embodiments described with reference to FIG. 5, when the rework is performed on the reworked dielectric lid 141, it may be necessary to change the position or thickness of the mode modifier 118_MM, which is the same as described with reference to FIG. 5. Therefore, detailed description thereof will be omitted.

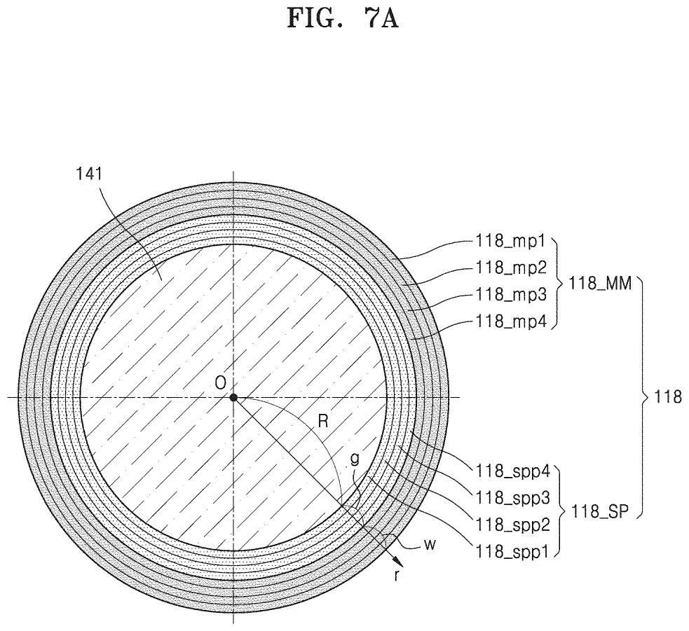

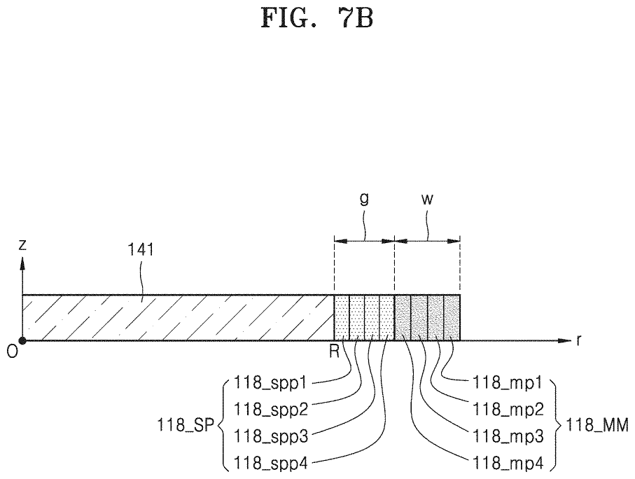

FIG. 7A is a plan view illustrating the mode modifier 118_MM and the dielectric spacer 118_SP according to some example embodiments of inventive concepts, and FIG. 7B is a cross-sectional view illustrating a cross-section taken in the radial direction r of FIG. 7A

Referring to FIGS. 7A and 7B, the mode modifier 118_MM is arranged around the reworked dielectric lid 141 with the dielectric spacer 118_SP therebetween.

The mode modifier 118_MM may include one or more mode modifying rings, for example, first, second, third, and fourth modifying rings 118_mp1, 118_mp2, 118_mp3, and 118_mp4, as modifying pieces. For example, the mode modifier 118_MM may sequentially include the first mode modifying ring 118_mp1, the second mode modifying ring 118_mp2, the third mode modifying ring 118_mp3, and the fourth mode modifying ring 118_mp4 that are concentrically arranged from the outermost side. In FIGS. 7A and 7B, the mode modifier 118_MM is illustrated as including four mode modifying rings. However, those of ordinary skill in the art would understand that the mode modifier 118_MM may include one, two, three, five, or more mode modifying rings.

Alternatively or additionally, the dielectric spacer 118_SP may include one or more spacer rings, for example, first, second, third, and fourth spacer rings 118_spp1, 118_spp2, 118_spp3, and 118_spp4, as spacer pieces. For example, the dielectric spacer 118_SP may sequentially include the first spacer ring 118_spp1, the second spacer ring 118_spp2, the third spacer ring 118_spp3, and the fourth spacer ring 118_spp4 that are concentrically arranged from the innermost side. In FIGS. 7A and 7B, the dielectric spacer 118_SP is illustrated as including four spacer rings. However, those of ordinary skill in the art would understand that the dielectric spacer 118_SP may include one, two, three, five, or more spacer rings. In some example embodiments, when the dielectric spacer 118_SP is vacuous or gaseous, boundaries among the spacer rings may be virtual ones.

Each of the first to fourth mode modifying rings 118_mp1, 118_mp2, 118_mp3, and 118_mp4 may be formed of the same material or different materials. That is, at least one of the first to fourth mode modifying rings 118_mp1, 118_mp2, 118_mp3, and 118_mp4 may be formed of a first material and at least one other may be formed of a second material.

As substrates W are repeatedly processed while using the reworked dielectric lid 141, the problem of product defects may occur again due to the generation of the particles. In this case, the rework may be performed again on the reworked dielectric lid 141. The rework may smoothen the surface of the quartz dome on the side facing the reaction space 182 (refer to FIG. 2) as described above.

When the rework is performed again, because the thickness of the reworked dielectric lid 141 additionally changes, the resonance characteristic in the reworked dielectric lid 141 may change again and the problem described with reference to FIG. 4B may occur. In this case, by exchanging one or more of the first to fourth spacer rings 118_spp1, 118_spp2, 118_spp3, and 118_spp4 with additional mode modifying rings in consideration of the changed resonance characteristic, as described above with reference to FIG. 4C, the resonance characteristic may be normalized. Alternatively or additionally, by exchanging one or more of the first to fourth mode modifying rings 118_mp1, 118_mp2, 118_mp3, and 118_mp4 with additional spacer rings considering the changed resonance characteristic, as described above with reference to FIG. 4C, the resonance characteristic may be normalized.

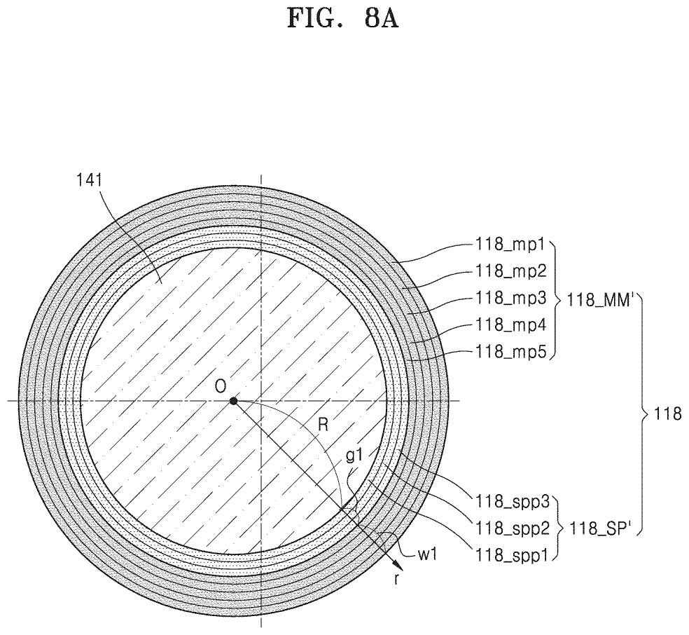

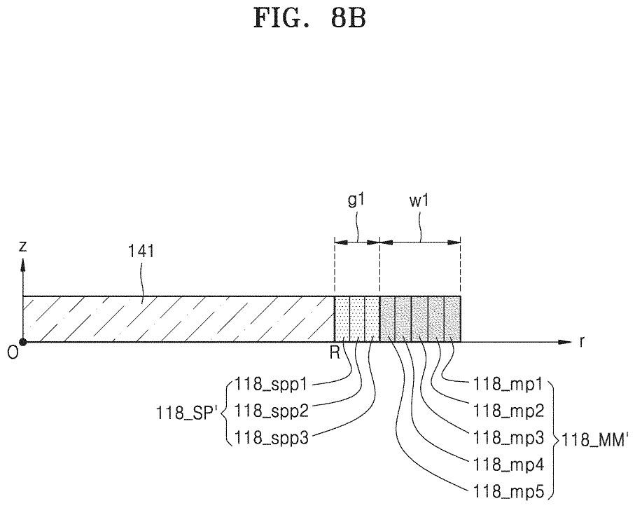

FIGS. 8A and 8B are a plan view and a side view illustrating an example in which the fourth spacer ring 118_spp4 of FIGS. 7A and 7B is replaced with a fifth mode modifying ring 118_mp5.

Referring to FIGS. 8A and 8B, in order to modify the change in the resonance characteristic in accordance with the rework performed on the reworked dielectric lid 141, the first to third spacer rings 118_spp1, 118_spp2, and 118_spp3 may be left and the fourth spacer ring 118_spp4 may be removed. Then, the fifth mode modifying ring 118_mp5 with sizes (for example, an outer diameter, an inner diameter, and/or a z direction height) equal to those of the fourth spacer ring 118_spp4 may be added in a position in which the fourth spacer ring 118_spp4 was provided.

A mode modifier 118_MM′ including the first to fifth mode modifying rings 118_mp1, 118_mp2, 118_mp3, 118_mp4, and 118_mp5 has a first width w1 increased from the first width w. In addition, a dielectric spacer 118_SP′ including the first to third spacer rings 118_spp1, 118_spp2, and 118_spp3 has a second width gl reduced from the second width g.

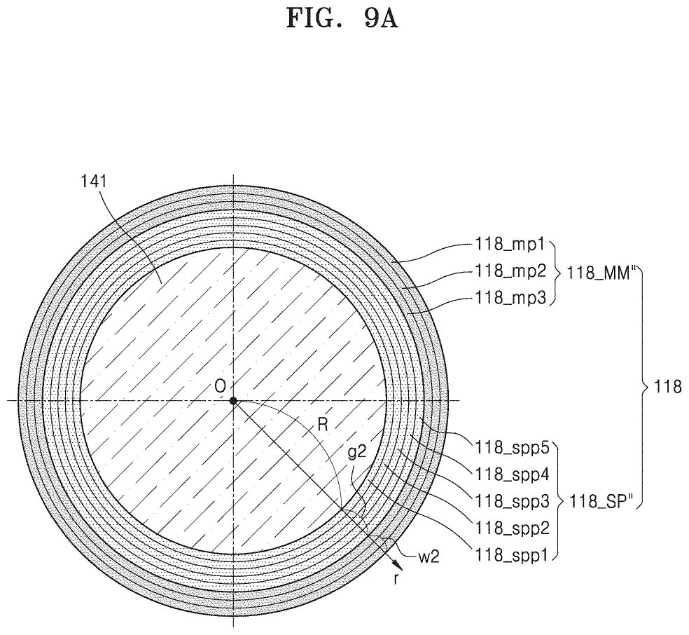

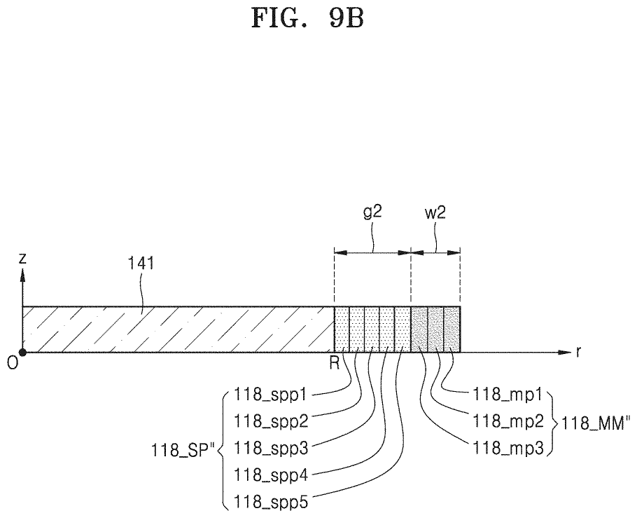

FIGS. 9A and 9B are a plan view and a side view illustrating an example in which the fourth mode modifying ring 118_mp4 of FIGS. 7A and 7B is replaced with a fifth spacer ring 118_spp5.

Referring to FIGS. 9A and 9B, in order to modify the change in the resonance characteristic in accordance with the rework performed on the reworked dielectric lid 141, the first to third mode modifying rings 118_mp1, 118_mp2, and 118_mp3 may be left and the fourth mode modifying ring 118_mp4 may be removed. Then, a fifth spacer ring 118_spp5 with sizes (for example, an outer diameter, an inner diameter, and/or a z direction height) equal to those of the fourth mode modifying ring 118_mp4 may be added in a position in which the fourth mode modifying ring 118_mp4 was provided.

A mode modifier 118_MM″ including the first to third mode modifying rings 118_mp1, 118_mp2, and 118_mp3 has a first width w2 reduced from the first width w. In addition, a dielectric spacer 118_SP″ including the first to fifth spacer rings 118_spp1, 118_spp2, 118_spp3, 118_spp4, and 118_spp5 has a second width g2 increased from the second width g.

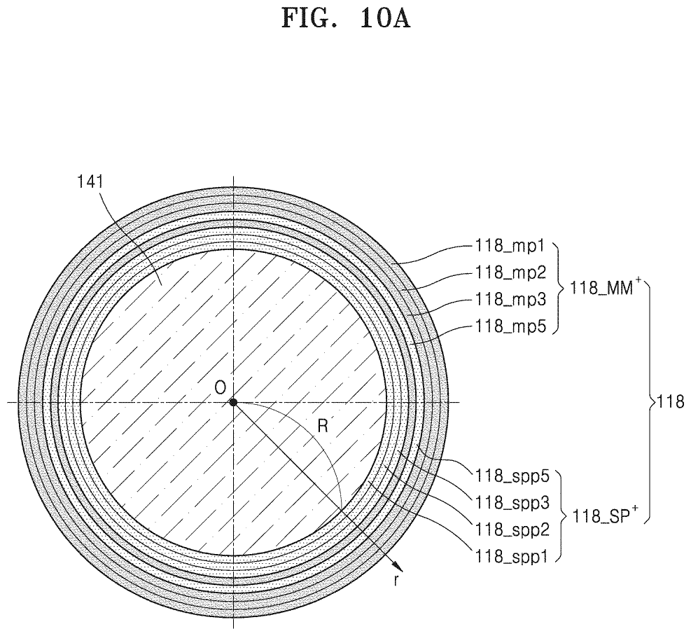

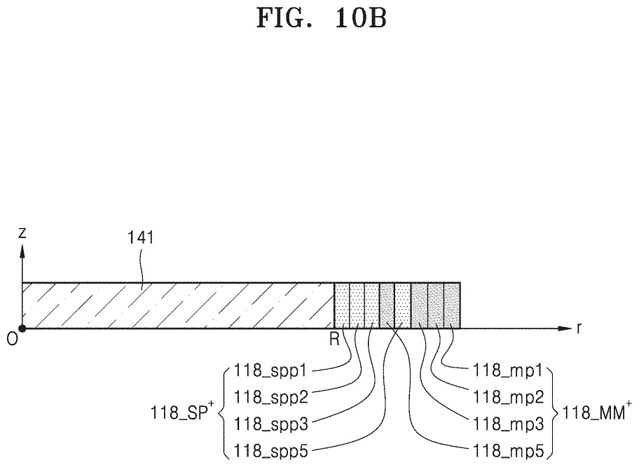

FIGS. 10A and 10B are a plan view and a side view illustrating an example in which the fourth spacer ring 118_spp4 of FIGS. 7A and 7B is replaced with the fifth mode modifying ring 118_mp5 and the fourth mode modifying ring 118_mp4 is replaced with the fifth spacer ring 118_spp5.

Referring to FIGS. 10A and 10B, in order to modify the change in the resonance characteristic in accordance with the rework performed on the reworked dielectric lid 141, the first to third spacer rings 118_spp1, 118_spp2, and 118_spp3 may be left and the fourth spacer ring 118_spp4 may be removed. Then, the fifth mode modifying ring 118_mp5 with the sizes (for example, the outer diameter, the inner diameter, and the z direction height) equal to those of the fourth spacer ring 118_spp4 may be added in the position in which the fourth spacer ring 118_spp4 was provided.

Alternatively or additionally, the first to third mode modifying rings 118_mp1, 118_mp2, and 118_mp3 may be left and the fourth mode modifying ring 118_mp4 may be removed. Then, the fifth spacer ring 118_spp5 with the sizes (for example, the outer diameter, the inner diameter, and the z direction height) equal to those of the fourth mode modifying ring 118_mp4 may be added in the position in which the fourth mode modifying ring 118_mp4 was provided.

In some example embodiments, the sum of all sizes of a mode modifier 118_MM⁺ in a radial direction may be equal to that in FIGS. 7A and 7B. In addition, the sum of all sizes of a dielectric spacer 118_SP⁺ in a radial direction may be equal to that in FIGS. 7A and 7B.

As described above, the change in the resonance characteristic in accordance with the rework performed on the dielectric lid 141 may be properly modified by varying the mode modifier 118_MM and the dielectric spacer 118_SP that are arranged outside the reworked dielectric lid 141. Those of ordinary skill in the art may achieve necessary adjustment of the resonance characteristic by investigating the resonance characteristic of the reworked dielectric lid 141 and properly combining and applying the mode modifiers 118_MM, 118_MM′, 118_MM″, and 118_MM⁺ and the dielectric spacers 118_SP, 118_SP′, 118_SP″, and 118_SP⁺ described with reference to FIGS. 5 to 10B.

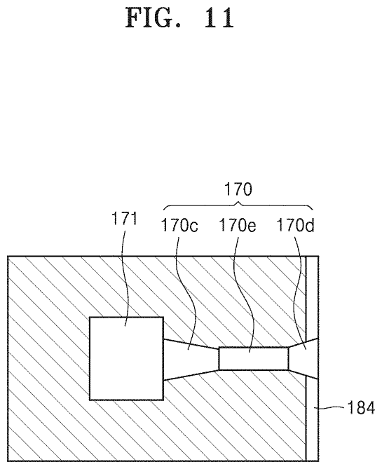

FIG. 11 is an enlarged view illustrating the region B of FIG. 2 in the substrate processing apparatus 100 according to some example embodiments of inventive concepts in detail.

Referring to FIG. 11, the second processing gas may be supplied to the second processing gas supply pipe 170 through the buffer 171.

As described above, the buffer 171 may be connected to the second processing gas supply source 173 and may receive the second processing gas. The buffer 171 annularly extends in the upper gas ring 114 of the chamber housing 110 and is connected to the plurality of second processing gas supply pipes 170 provided along an inner wall of the chamber housing 110.

The plurality of second processing gas supply pipes 170 may contribute to preventing or reducing the particles from falling down onto the substrate W in cooperation with the mode modifiers 118_MM, 118_MM′, 118_MM″, and 118_MM⁺ described with reference to FIGS. 3 to 10. Specifically, the second processing gas discharged from the plurality of second processing gas supply pipes 170 may prevent or reduce the likelihood of the particles from falling down onto the substrate W by making a flow of the second processing gas by a convection more dominant than a flow of the second processing gas by diffusion, in an upper portion of the susceptor.

In some example embodiments, each of the plurality of second processing gas supply pipes 170 may include a convergent unit 170c and a divergent unit 170d. The divergent unit 170d may be closer to the reaction space 182 than the convergent unit 170c is. In addition, an extension unit 170e may be further between the convergent unit 170c and the divergent unit 170d. Each of, or at least one of, the convergent unit 170c, the divergent unit 170d, and the extension unit 170e are a structure or assembly, e.g. are a pipe having a first end and a second end. The convergent unit 170c and the divergent unit 170d may connect to the extension unit 170e, e.g. may be connected via welding and/or may be threaded.

An inner diameter of the convergent unit 170c may be gradually reduced from an entrance connected to the buffer 171 to an exit connected to the extension unit 170e. An inner diameter of the divergent unit 170d may gradually increase from an entrance connected to the extension unit 170e to an exit connected to the reaction space 182. The convergent unit 170c and the divergent unit 170d may be tapered. The increase and/or reduction of the inner diameter may be linear or non-linear.

An entrance of the extension unit 170e may be connected to the exit of the convergent unit 170c and an exit of the extension unit 170e may be connected to the entrance of the divergent unit 170d. An inner diameter of the extension unit 170e may be uniform. The extension unit 170e may be cylindrical.

A linear velocity of the second processing gas in the center of the second processing gas supply pipe 170 may be at least partially ultrasonic. A speed of the second processing gas may depend on pressure in the buffer 171, pressure in the reaction space 182, shapes of the convergent unit 170c and the divergent unit 170d, and a volumetric flow rate of the second processing gas.

A supply speed of the second processing gas is insufficient in the second processing gas supply pipe provided in the inner wall of the conventional chamber housing so that the flow of the second processing gas by the convection cannot affect an upper surface of the substrate. Therefore, mass transfer of the second processing gas to the upper surface of the substrate is achieved by diffusion driven by a concentration gradient of the second processing gas. In such a case, the second processing gas does not contribute to preventing or reducing the particles generated by corrosion of the dielectric lid from falling down onto the substrate.

In contrast, because the second processing gas supplied by the second processing gas supply pipe 170 according to embodiments is transferred to an upper portion of the substrate W by the convention as well as the diffusion, the second processing gas can contribute to preventing or reducing the particles generated by the corrosion of the dielectric lid from falling down onto the substrate W.

In some example embodiments, the second processing gas supply pipe 170 may include a de Laval nozzle.

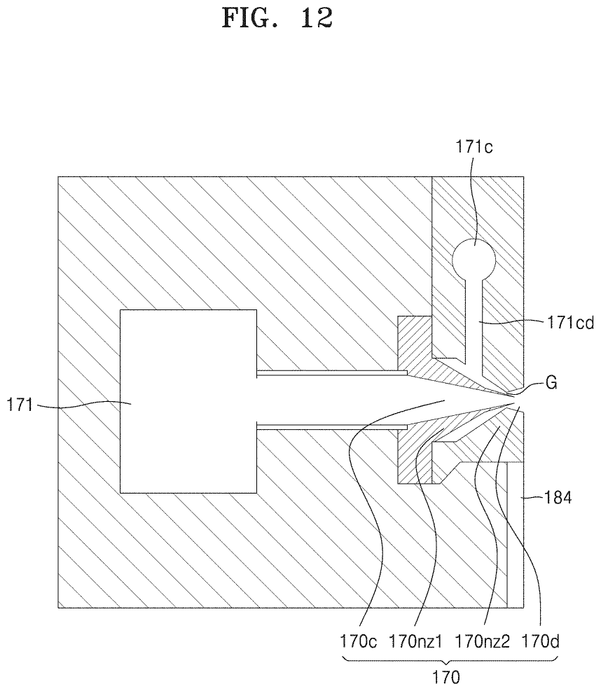

FIG. 12 is an enlarged view illustrating the region B of FIG. 2 in the substrate processing apparatus 100 according to some example embodiments of inventive concepts in detail.

Referring to FIG. 12, the second processing gas may be supplied to a plurality of second processing gas supply pipes 170a through the buffer 171. The plurality of second processing gas supply pipes 170a may be provided along the inner wall of the chamber housing 100.

In some example embodiments, each of the plurality of second processing gas supply pipes 170a may include a first sub-nozzle 170nz1 and a second sub-nozzle 170nz2.

The first sub-nozzle 170nz1 may include the convergent unit 170c and may have an end protruding toward the reaction space 182. The protruding end is open toward the reaction space 182 as an exit of the convergent unit 170c.

The second sub-nozzle 170nz2 includes the divergent unit 170d, and the entrance of the divergent unit 170d may surround the protruding end of the first sub-nozzle 170nz1 with a gap G therebetween. The exit of the divergent unit 170d may be connected to the reaction space 182.

The second processing gas supplied through the buffer 171 is supplied to the divergent unit 170d through the convergent unit 170c. In addition, a carrier gas supplied through a carrier gas buffer 171c is supplied to the divergent unit 170d through the gap G between the end of the first sub-nozzle 170nz1 and the second sub-nozzle 170nz2. The second processing gas may be mixed with the carrier gas in the divergent unit 170d and may be supplied to the reaction space 182.

The carrier gas supplied through the carrier gas buffer 171c may annularly extend in the chamber housing 110 like the buffer 171 and may be connected to the second sub-nozzle 170nz2 through a conduit 171cd.

In FIG. 12, it is illustrated that the first sub-nozzle 170nz1 is separate from the second sub-nozzle 170nz2. However, the first sub-nozzle 170nz1 and the second sub-nozzle 170nz2 may be integrated with each other.

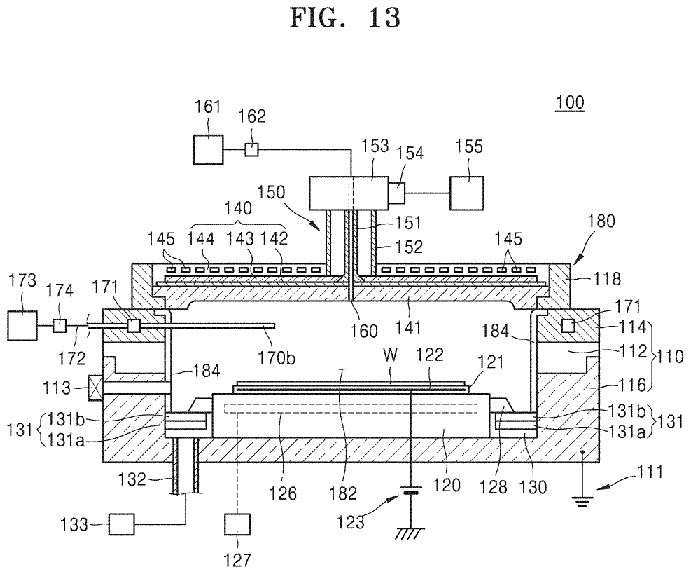

FIG. 13 is a side sectional view illustrating the substrate processing apparatus 100 including a second processing gas supply pipe 170b according to some example embodiments of inventive concepts.

Referring to FIG. 13, one end of the second processing gas supply pipe 170b may be connected to the buffer 171 and the other end thereof may extend to the upper portion of the susceptor 120 in a horizontal direction. The second processing gas supply pipe 170b may be a common conduit and may directly guide the second processing gas to the upper portion of the susceptor 120. Therefore, the second processing gas may directly reach the upper portion of the substrate W not by diffusion and may contribute to preventing or reducing the particles from falling down onto the substrate W.

In some embodiments, the second processing gas supply pipe 170b may include a convergent unit and a divergent unit like in the embodiments illustrated in FIGS. 11 and 12. However, inventive concepts is not limited thereto.

While inventive concepts has been particularly shown and described with reference to embodiments thereof, it will be understood that various changes in form and details may be made therein without departing from the spirit and scope of the following claims.

1. A substrate processing apparatus comprising:
a chamber housing with an upper portion opened, the chamber housing defining a reaction space;
a susceptor configured to support a substrate in the chamber housing; and
a dielectric cover covering an upper portion of the chamber housing,
wherein the dielectric cover includes,
a dielectric lid, and
a mode modifying assembly arranged around the dielectric lid to be spaced apart from the dielectric lid, the mode modifying assembly configured to adjust a distance from the dielectric lid.

2. The substrate processing apparatus of claim 1, wherein the mode modifying assembly comprises a metal.

3. The substrate processing apparatus of claim 1, wherein the dielectric lid comprises quartz.

4. The substrate processing apparatus of claim 3, wherein the dielectric lid and the mode modifying assembly are apart from each other with a dielectric spacer therebetween.

5. The substrate processing apparatus of claim 4, wherein the mode modifying assembly comprises a plurality of modifying pieces arranged around the dielectric lid.

6-7. (canceled)

8. The substrate processing apparatus of claim 4, wherein the dielectric constant of the dielectric spacer is between 1 to 15.

9. The substrate processing apparatus of claim 1, further comprising:
a gas supply pipe on a side wall of the chamber housing, and
wherein the gas supply pipe is configured to supply a reaction gas in order to reduce a likelihood of particles from falling down onto the substrate in cooperation with the mode modifying assembly.

10. The substrate processing apparatus of claim 9, wherein the gas supply pipe comprises a convergent structure and a divergent structure, and
wherein the convergent structure and the divergent structure are serially arranged so that the divergent structure is closer to the reaction space of the chamber housing.

11. The substrate processing apparatus of claim 10, wherein a speed of the reaction gas in the divergent structure is at least partially ultrasonic.

12. The substrate processing apparatus of claim 10, wherein the gas supply pipe comprises:
a first sub-nozzle including the convergent structure and having an end protruding toward the reaction space of the chamber housing; and
a second sub-nozzle including the divergent structure of which an entrance surrounds the end of the first sub-nozzle with a gap therebetween.

13. (canceled)

14. The substrate processing apparatus of claim 9, wherein the gas supply pipe extends from an inner side wall of the chamber housing to an upper portion of the susceptor in a horizontal direction.

15. A substrate processing apparatus comprising:
a chamber housing with an upper portion opened, the chamber housing defining a reaction space and including a gas supply pipe in a side wall;
a susceptor configured to support a substrate in the chamber housing; and
a dielectric cover covering an upper portion of the chamber housing,
wherein the gas supply pipe is configured such that, in an upper portion of the susceptor, a flow of a gas by a convection is more dominant than a flow of a gas by diffusion.

16. The substrate processing apparatus of claim 15, wherein the gas supply pipe extends in a horizontal direction from a side wall of the chamber housing to an upper portion of the susceptor.

17. The substrate processing apparatus of claim 15, wherein the gas supply pipe is configured such that a speed of the gas in an exit of the gas supply pipe is at least partially ultrasonic.

18. (canceled)

19. The substrate processing apparatus of claim 15, wherein the dielectric cover comprises a dielectric lid and a mode modifying assembly, and
wherein the mode modifying assembly comprises a metal.

20. The substrate processing apparatus of claim 19, wherein the mode modifying assembly is spaced apart from the dielectric lid and is arranged around the dielectric lid and includes one or more mode modifying rings.

21. The substrate processing apparatus of claim 20, wherein the mode modifying assembly is apart from the dielectric lid with a dielectric spacer therebetween, and
the dielectric spacer comprises one or more spacer rings.

22-23. (canceled)

24. The substrate processing apparatus of claim 19, wherein the mode modifying assembly comprises a plurality of modifying pieces arranged around the dielectric lid, and
each of the plurality of mode modifying pieces is configured such that a position of the each of the plurality of mode modifying pieces can be modified in a radial direction of the mode modifying assembly.

25. The substrate processing apparatus of claim 19, wherein the dielectric lid includes a reworked quartz dome.

26. (canceled)

27. A substrate processing apparatus comprising:
a chamber housing with an upper portion opened, the chamber housing defining a reaction space;
a susceptor configured to support a substrate in the chamber housing;
a dielectric cover including a reworked dielectric lid and a mode modifying assembly arranged around the reworked dielectric lid, the mode modifying assembly spaced apart from the reworked dielectric lid and covering an upper portion of the chamber housing;
a high frequency antenna on the dielectric lid;
a microwave generator connected to the high frequency antenna; and
a plurality of gas supply pipes provided on a side wall of the chamber housing,
wherein the mode modifying assembly is apart from the dielectric lid with a dielectric spacer therebetween, and
the plurality of gas supply pipes are configured such that a flow of a gas by a convection is more dominant than that of a gas by diffusion in an upper portion of the susceptor.
